(19) United States
(12) Patent Application Publication
(10) Pub. No.: US 2004/0047410 A1
(43) Pub. Date: Mar. 11, 2004

(54) Method and apparatus for compensating for phase error of digital signal

(76) Inventors: Sung-Woo Choi, Jeonrabuk-do (KR); Hoon Lee, Daejeon (KR); Jong-Won Kim, Daejeon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/335,037

(22) Filed: Dec. 31, 2002

(30) Foreign Application Priority Data
Sep. 5, 2002 (KR) 2002-53451

(51) Int. Cl. H03K 5/159; H03H 7/30; H03H 7/40

(52) U.S. Cl. 375/232; 375/233

(57) ABSTRACT

A method and apparatus for compensating for phase errors of a digital signal are provided. An equalizer compensates for an amplitude distortion of a received signal caused by a channel and outputs an equalized signal after a first predetermined delay time elapses. A first multiplying means complex multiplies the equalized signal by a phase corrected signal and outputs a first multiplied value. A first multiplexing means selectively outputs either the received signal or the first multiplied value based upon whether the first predetermined time has elapsed. A phase compensating means sets an initial value of a local oscillator based upon an average value of phase errors of the received signal before the first predetermined time elapses, and removes phase errors existing in the first multiplied value after the first predetermined time elapses.

This application claims the priority of Korean Patent Application No. 2002-53451, filed Sep. 5, 2002, in the Korean Intellectual Property Office, the disclosure of which is incorporated herein in its entirety by reference.

### BACKGROUND OF THE INVENTION

1. Field of the Invention

The present invention relates to a method and apparatus for compensating for a phase error of a digital signal and, more particularly, to a method and apparatus for compensating for a phase error of a digital signal using an adaptive equalizer and a phase compensator.

2. Description of the Related Art

An adaptive equalizer of a digital communications receiver is used to compensate for distortion of a received signal caused by a transmission line. Typically, when a signal that has passed through the adaptive equalizer goes through a signal discriminator, an amplitude error and a phase error are produced. The phase error produced in the digital communications receiver includes an error due to phase distortion by a communications channel and an initial phase difference between transmitting and receiving oscillators, and an error due to a frequency difference between the transmitting and the receiving oscillators.

In order to compensate for the phase error, there is a way to transmit the error to a carrier demodulator and to control a carrier. In such a way, however, it is difficult to detect and compensate for the error quickly, because the phase error can be acquired only after an output signal of the carrier demodulator passes through pre-stage filters. Therefore, as shown in FIG. 1, it is conventional to use an equalizer, a phase compensator, and an original signal discriminator to directly compensate for the phase error in the output of the equalizer.

In this regard, U.S. Pat. No. 5,506,871 discloses a technique using two sequentially connected phase compensators to improve phase compensation performance, and U.S. Pat. No. 5,471,408 discloses a method of phase compensation using acquisition and tracking modes based upon errors being produced. While these conventional methods may cope with a situation in which phases vary as time elapses, such methods are not appropriate in a situation in which the phase compensator is mainly used to obtain a high S/N (signal to noise) ratio within a short time, as in a burst situation in which signals are transmitted frame by frame. Further, in a situation in which signals are not yet discriminated to a certain extent, using the equalizer and the phase compensator simultaneously may cause a delay in convergence of MSE of the equalizer.

In considering the above problem, there is a way to expedite tracking and compensation for phase errors by using the equalizer for an initial predetermined time to equalize a received signal to some extent and, then, using the phase compensator. In such a way, most of the phase errors should be compensated for using the equalizer so that the phase compensator can stably operate and compensate for the remaining phase errors. However, in the event that a series of training signals is short as in a burst mode modem, it is difficult for the equalizer to compensate for most of the phase errors as well as amplitude errors within a short time.

### SUMMARY OF THE INVENTION

To solve the above and other problems, it is an object of the present invention to provide a method and apparatus for compensating for phase errors of a digital signal, which tracks and compensates for the phase errors quickly, and reduces a burden on an equalizer to compensate for the phase errors as well as amplitude errors within a limited time using a series of training signals.

An apparatus for compensating for phase errors of a digital signal according to the present invention comprises an equalizing means for outputting, when a first predetermined delay time elapses, an equalized signal in which amplitude distortion of a received signal due to a channel is compensated for; a first multiplying means for multiplying,, in complex form, the equalized signal by a compensation signal in which a phase is compensated for and for outputting a first multiplied value; a first multiplexing means for selectively outputting either the received signal or the first multiplied value inputted from the first multiplying means based upon whether the first predetermined delay time has elapsed; and a phase compensation means for setting an initial value of a local oscillator based upon an average value of phase errors of the received signal inputted from the first multiplexing means before the first predetermined delay time elapses, and for removing phase errors existing in the first multiplied value provided from the first multiplexing means after the first predetermined delay time elapses.

The apparatus for compensating for phase errors of a digital signal according to the present invention further comprises a signal discriminating means for discriminating an original signal from a signal inputted from the first multiplexing means; a subtracting means for comparing input and output signals of the signal discriminating means and for detecting errors; a second multiplying means for multiplying an output signal of the subtracting means by an output signal of the phase compensation means and for outputting a second multiplied value; a third multiplying means for multiplying the output signal of the signal discriminating means by the output signal of the phase compensation means and for outputting a third multiplied value; a first switching means for providing the output signal of the first multiplexing means to the subtracting means when the first predetermined delay time elapses; a second switching means for providing the output signal of the signal discriminating means to the subtracting means and to the third multiplying means when the first predetermined delay time elapses; and an error controlling means for controlling an error value corresponding to the second multiplied value and for providing the error value to the equalizing means.

In the apparatus for compensating for phase errors of a digital signal according to the present invention, the equalizing means comprises a forward equalizing means for equalizing the received signal; a backward equalizing means for equalizing the signal inputted from the signal discriminating means; an adding means for adding an output signal from the forward equalizing means and an output signal from the backward equalizing means, and for outputting an added value; and a coefficient updating means for updating an operational coefficient of the forward equalizing means and the backward equalizing means based upon the error value inputted from the error controlling means after a second predetermined delay time elapses.

In the apparatus for compensating for phase errors of a digital signal according to the present invention, the error controlling means provides the equalizing means with a zero (0) value before the second predetermined delay time elapses and with the error value corresponding to the second multiplied value inputted from the second multiplying means after the second predetermined delay time elapses.

In the apparatus for compensating for phase errors of a digital signal according to the present invention, the phase compensation means comprises a first phase detecting means for detecting phase errors of the signal inputted from the first multiplexing means and for outputting first phase detected signals; a second phase detecting means for detecting phase errors corresponding to integer multiples of π/2 from phase differences between the signal inputted from the first multiplexing means and a series of training signals, and for outputting second phase detected signals; a third phase detecting means for detecting phase errors of the signal inputted from the first multiplexing means and for outputting third phase detected signals; an adding means for adding the first phase detected signals and the second phase detected signals, and for outputting phase difference values; an averaging means for averaging the phase difference values, and for outputting an average value; a loop filtering means for outputting filtered phase errors discriminated from the third phase detected signals; a demultiplexing means for providing the signal inputted from the first multiplexing means to the first phase detecting means and to the second phase detecting means before the first predetermined delay time elapses, and to the third phase detecting means after the first predetermined delay time elapses; a second multiplexing means for outputting the average value before the first predetermined delay time elapses and for outputting the phase errors after the first predetermined delay time elapses; a numerically controlled oscillating means for integrating the phase errors inputted from the second multiplexing means with the average value inputted from the second multiplexing means as an initial value when the first predetermined delay time elapses and for outputting a compensation value.

In the apparatus for compensating for phase errors of a digital signal according to the present invention, the bandwidth of the loop filtering means is reduced after the second predetermined delay time elapses.

A method for compensating for phase errors of a digital signal according to the present invention comprises the steps of calculating an average phase error value of a received signal before a first predetermined delay time elapses; outputting, after a first predetermined delay time elapses, an equalized signal in which amplitude distortion of the received signal due to a channel is compensated for; multiplying, in complex form, the equalized signal by a compensation signal in which phase is compensated for and outputting a first multiplied value; and removing phase errors existing in the first multiplied value.

The method for compensating for phase errors of a digital signal according to the present invention further comprises the steps of discriminating an original signal from the received signal and the equalized signal, which are selectively inputted based upon whether the first predetermined delay time has elapsed, and outputting a discriminated signal; calculating a difference value between the discriminated signal and the compensation signal when the first predetermined delay time elapses, and multiplying the difference value by the compensation signal and outputting a second multiplied value; producing an error value corresponding to the second multiplied value; updating an operational coefficient of the equalizer based on the error value; and multiplying the discriminated signal by the compensation signal when the first predetermined delay time elapses and providing a third multiplied value to the equalizer.

In the method for compensating for phase errors of a digital signal according to the present invention, the step of updating an operational coefficient is performed after a second predetermined delay time elapses.

In the method for compensating for phase errors of a digital signal according to the present invention, the step of producing the error value includes the steps of outputting a zero (0) value as the error value required by the equalizer before the second predetermined delay time elapses, and outputting the second multiplied value after the second predetermined delay time elapses.

In the method for compensating for phase errors of a digital signal according to the present invention, the step of outputting the compensation signal includes the steps of (a) detecting phase errors of the received signal and outputting first phase detected signals; (b) detecting phase errors corresponding to integer multiples of π/2 from phase differences between the signal inputted from the first multiplexing means and a series of training signals, and for outputting second phase detected signals; (c) adding the first phase detected signals and the second phase detected signals, and outputting phase difference values; (d) averaging the phase difference values and outputting an average value; (e) detecting phase errors with respect to the first multiplied value and outputting third phase detected signals; (f) receiving the third phase detected signals and discriminating the phase errors; (g) integrating the phase errors with the average value as an initial value when the first predetermined delay time elapses and outputting a compensation value, wherein the steps (a) through (d) are repeated before the first predetermined delay time elapses, and the steps (e) through (g) are performed after the first predetermined delay time elapses.

In the method for compensating for phase errors of a digital signal according to the present invention, the step of discriminating phase errors includes the step of discriminating the phase errors by reducing a bandwidth for discriminating the phase errors when the second predetermined time elapses.

According to the present invention, since the equalizer operates after most of the phase errors are removed during a natural delay time within the equalizer, the equalizer is dedicated to removing interference between symbols and has less of a burden to compensate for phase errors. Therefore, according to the present invention, channel equalization performance is improved while phase compensation time is reduced significantly.

### BRIEF DESCRIPTION OF THE DRAWINGS

The above and other objects and advantages of the present invention will become more apparent by describing, in detail, preferred embodiments thereof with reference to the attached drawings in which:

FIG. 1 is a block diagram of a conventional phase error compensator;

FIG. 2 is a block diagram of a phase error compensator according to the present invention;

FIG. 3 is a block diagram of a forward equalizer included in the phase error compensator according to the present invention;

FIG. 4 is a block diagram of a phase compensator included in the phase error compensator according to the present invention;

FIG. 5 is a flow chart for explaining a method for compensating for phase errors according to the present invention;

FIGS. 6a and 6b are flow charts for explaining in more detail a method for compensating for phase errors according to the present invention;

FIG. 7 is a chart illustrating outputs of a numerically controlled oscillator (NCO) according to different phase compensating methods; and

FIG. 8 is a chart illustrating mean square error (MSE) characteristics according to the different phase compensating methods.

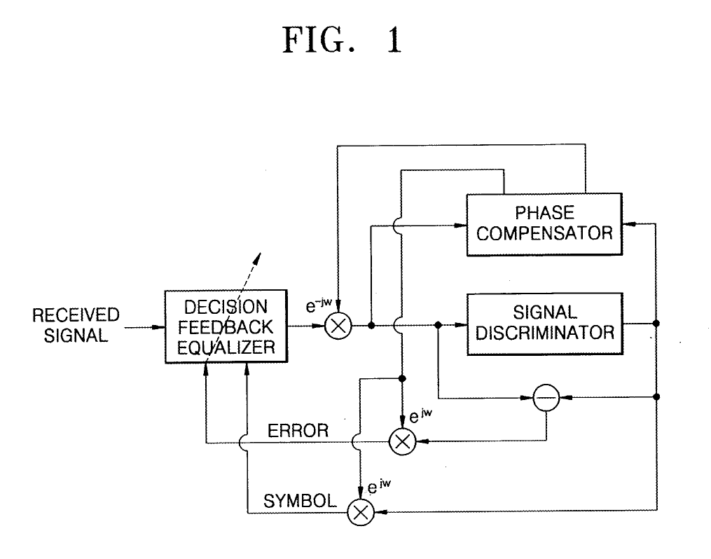

### DETAILED DESCRIPTION OF THE INVENTION

An apparatus for compensating for phase errors of a digital signal according to the present invention minimizes a burden on an equalizer to compensate for the phase errors using a two-stage phase compensator, and improves channel equalization effects. The two-stage phase compensator operates in two stages using a natural delay within the equalizer. Initial coefficients of taps of the equalizer are set to zero, except for a center tap (k-th tap). Accordingly, the output of the equalizer is zero before a first input reaches the center tap. Since a first output of the equalizer is produced when an input is multiplied by the value of the center tap, there is a delay before the input reaches the center tap.

A first stage operation of the two-stage phase compensator utilizes the above natural delay. While a conventional phase compensator utilizes an output from the equalizer as its input, the phase compensator according to the present invention receives an input of the equalizer together with the output of the equalizer so as to obtain initial phase errors and calculate an average value of the phase errors while the output of the equalizer is zero. If the average value is set as an initial value of a numerically controlled oscillator, then a second stage operation of the phase compensator is enabled. The second stage operation is divided into two modes based upon a response time. For a certain time period after the equalizer begins to produce non-zero outputs, the loop filter with fast response time is used to quickly track any remaining phase errors. However, updating the coefficient of the equalizer is prohibited during this time period.

After this time period and after most of the phase compensations are made, it is possible to update the coefficients of the equalizer so that the equalizer is dedicated to removing interference between symbols. If the equalizer operates stably by removing the interference between symbols that have passed through a channel, the loop filter with slow response time is used to remove phase differences due to a frequency difference of transmitting and receiving oscillators. As described above, according to the present invention, quick phase compensation is achieved using a two-stage phase compensator, and equalization performance is improved by controlling the operation time of an equalizer so that the equalizer is dedicated to removing interference between symbols without a burden of phase compensation.

A preferred embodiment of a method and apparatus for compensating for phase errors of a digital signal will be explained in more detail herein below.

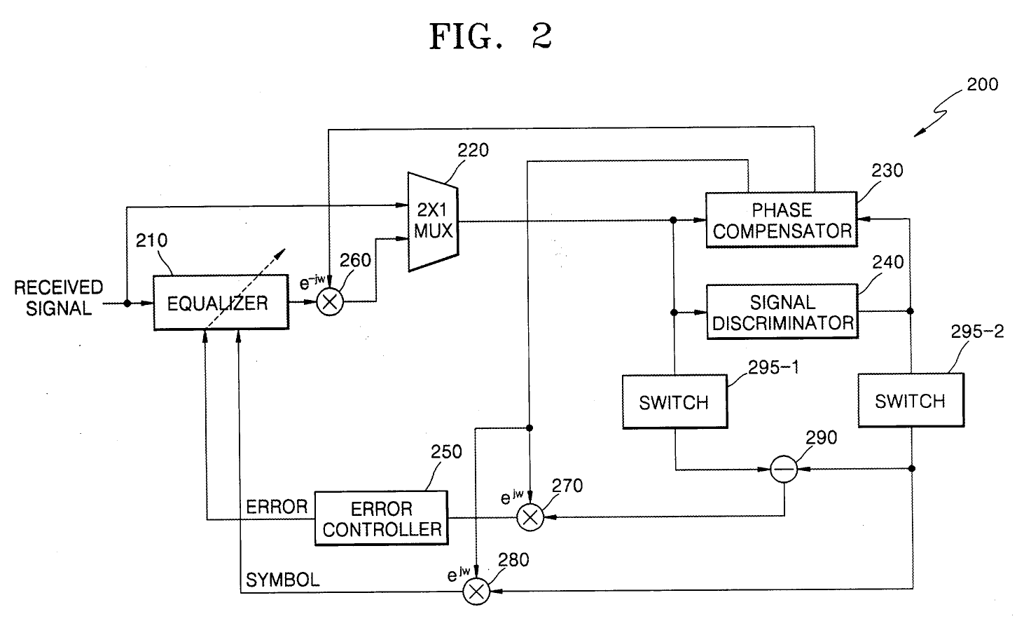

FIG. 2 is a block diagram of an apparatus for compensating for phase errors according to the present invention. Referring to FIG. 2, an apparatus 200 for compensating for phase errors according to the present invention includes an equalizer 210, a first multiplexer 220, a phase compensator 230, a signal discriminator 240, an error controller 250, a first multiplier 260, a second multiplier 270, a third multiplier 280, a subtracting unit 290, a first switch 295-1, and a second switch 295-2.

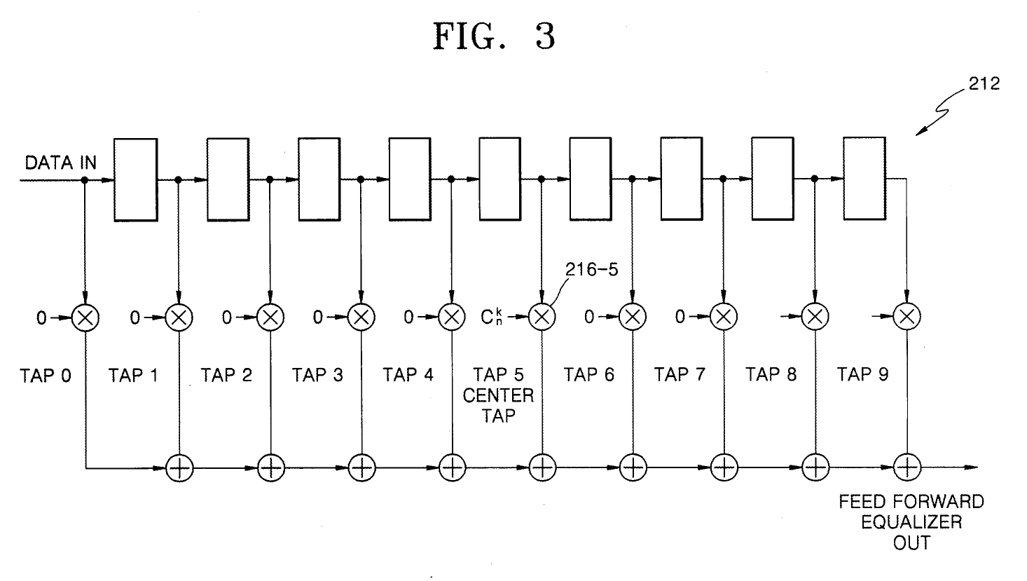

The equalizer 210 is a decision feedback equalizer having a forward equalizer and a backward equalizer. The schematic arrangement of the forward equalizer 212 equipped in the equalizer 210 is shown in FIG. 3. Referring to FIG. 3, if a center tap of the equalizer is the k-th tap 216-5, the equalizer 210 provides no outputs before k-1 symbols are inputted to the equalizer 210, since the inputs to the equalizer 210 are multiplied by an initial value of zero.

The first multiplexer 220 selects one of the signal input to the equalizer 210 and the signal output from the equalizer 210 as an input signal to the phase compensator 230. The first multiplexer 220 provides the input of the equalizer 210 to the phase compensator 230 during an internal delay time of the equalizer 210, and provides the output of the equalizer 210 to the phase compensator 230 after a non-zero output of the equalizer 210 begins to come out. A counter (not shown) decides whether the internal delay time elapsed.

The phase compensator 230 operates as a first stage phase compensator if the output of the equalizer 210 is zero, and as a second stage phase compensator from the instant when a non-zero output of the equalizer 210 comes out. The phase compensator 230 removes most of the phase errors during operation as the first stage phase compensator, and detects and tracks the remaining phase errors during operation as the second stage phase compensator.

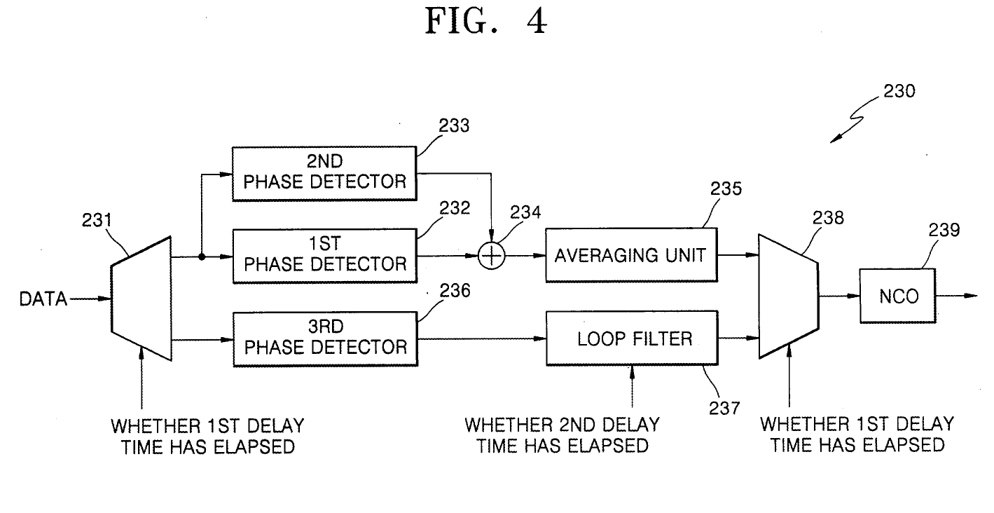

FIG. 4 is a block diagram of the two-stage phase compensator. Referring to FIG. 4, the two-stage phase compensator 230 includes a demultiplexer 231, a first phase detector 232, a second phase detector 233, an adder 234, an averaging unit 235, a third phase detector 236, a loop filter 237, a second multiplexer 238, and a numerically controlled oscillator (NCO) 239.

The demultiplexer 231 provides an input signal provided from the first multiplexer 220 to the first phase detector 232 and the second phase detector 233 before the internal delay time of the equalizer 210 elapses, and to the third phase detector 236 after the internal delay time of the equalizer elapses.

The first phase detector 232 and the third phase detector 236 detect phase errors of the input signal provided from the demultiplexer 231, and output a first phase detected signal and a third phase detected signal, respectively. The second phase detector 233 detects phase errors corresponding to integer multiples of π/2 from the phase difference between the input signal provided from the demultiplexer 231 and a series of training signals, and outputs a second phase detected signal.

If the input of the first phase detector 233 is qₖ, a value provided from the signal discriminator 240 in response to qₖ is Aₖ, the phase of a signal is θₖ, and a phase to be recovered is φₖ, then a phase difference ε′ₖ in the event that a phase difference (θₖ−φₖ) is small can be obtained using the following equations:

$$\begin{matrix}{θ}_{k} - {φ}_{k} = sin ( {θ}_{k} - {φ}_{k} ) = sin ( {ε}_{k}^{′} ) & ( 1 ) \\ sin ( {θ}_{k} - {φ}_{k} ) = Im [ \frac{{q}_{k} {A}_{k} *}{\vert {A}_{k} {\vert}^{2}} ] = \frac{Im ( {q}_{k} {A}_{k} *)}{\vert {q}_{k} \vert \vert {A}_{k} \vert} & ( 2 ) \\ {ε}_{k}^{′} = Im ( {q}_{k} {A}_{k} *) & ( 3 )\end{matrix}$$

While the above equations can be used in the event that the phase difference is small, another method is needed to detect a phase difference greater than 45 degrees. In the case of a receiver using a series of training signals, a phase difference of n×π/2 can be detected using the series of training signals. Therefore, in the event that the phase compensator operates as the first stage phase compensator, the total phase difference is obtained by adding the value obtained from the first phase detector 232 and the value from the second phase detector 233.

The adder 234 calculates the phase difference value by adding the first phase detected signal and the second phase detected signal. The averaging unit 235 averages the phase difference value, and provides the average value to the NCO 239 so that the NCO 239 utilizes the average value as an initial value for the second stage operation. Therefore, during the second stage operation, the phase compensator 230 compensates for the remaining phases based on the starting point obtained from the first stage operation.

The loop filter 237 detects and outputs phase errors from the third phase detected signal. The operation of the loop filer used in the second stage operation can be divided into two steps in terms of time. In the beginning of the operation, the bandwidth of the loop filter is expanded so as to detect the phase quickly. When the equalizer 210 starts to operate stably, the bandwidth of the loop filter is reduced so as to track remaining phase errors due to a frequency difference, etc. The reference time for changing the stage of operation of the loop filter 237 is determined by experiments, and a counter (not shown) is used to determine whether the reference time elapses.

The second multiplexer 238 provides the input signal provided from the loop filter 237 to the NCO 239 after the internal delay time of the equalizer 210 elapses.

The NCO 239 integrates the output of the loop filter 237 through an integrator to obtain a phase difference, and produces a compensating signal e^{jw} that is able to compensate for the phase errors. The output of the NCO 239 is provided to the first multiplier 260 so as to compensate for the phase errors of the outputs from the equalizer 210.

As described above, the operation in the event of using the equalizer 210 and the phase compensator 230 includes the steps in which (a) the phase compensator 230 operates as a first stage phase compensator when an output is not yet provided from the equalizer 210 while the input to the equalizer 210 is provided, (b) the phase compensator 230 operates as the second stage phase compensator from the time when the equalizer 210 provides an output and compensates for the phase errors quickly by expanding the bandwidth of the loop filter 237, and (c) in the state that the phase is compensated for, the equalizer 210 is dedicated to removing interference between symbols and the phase compensator 230 stably removes remaining phase errors by reducing the bandwidth of the loop filter 237.

The signal discriminator 240 discriminates an original signal from the signal inputted from the first multiplexer 220. The error controller 250 produces an error for updating the equalizer 210 in response to a signal that is received from the second multiplier 270. The input to the backward equalizer (not shown) and the error for updating a coefficient of the equalizer 210 must be produced from the time when the output of the equalizer 210 is not zero. For this purpose, there are provided the first switch 295-1 for providing the input signal of the signal discriminator 240 to the subtracting unit 290 starting from the second stage of phase compensation and the second switch 295-2 for connecting the output signal of the signal discriminator 240 to the third multiplier 280.

The first multiplier 260 directly multiplies the output of the equalizer 210 by the output of the phase compensator 230 and provides the multiplication result as an output. The subtracting unit 290 produces an error by comparing the input and the output of the signal discriminator 240 and outputs the error to the second multiplier 270. The second multiplier 270 recovers the phase before compensation by multiplying the error inputted from the subtracting unit 290 and the output of the phase compensator 230, and the multiplication result is inputted into the error controller 250. The third multiplier 280 recovers the phase by multiplying the signal inputted from the signal discriminator 240 and the output of the phase compensator 230, and the multiplication result is inputted into the backward equalizer (not shown).

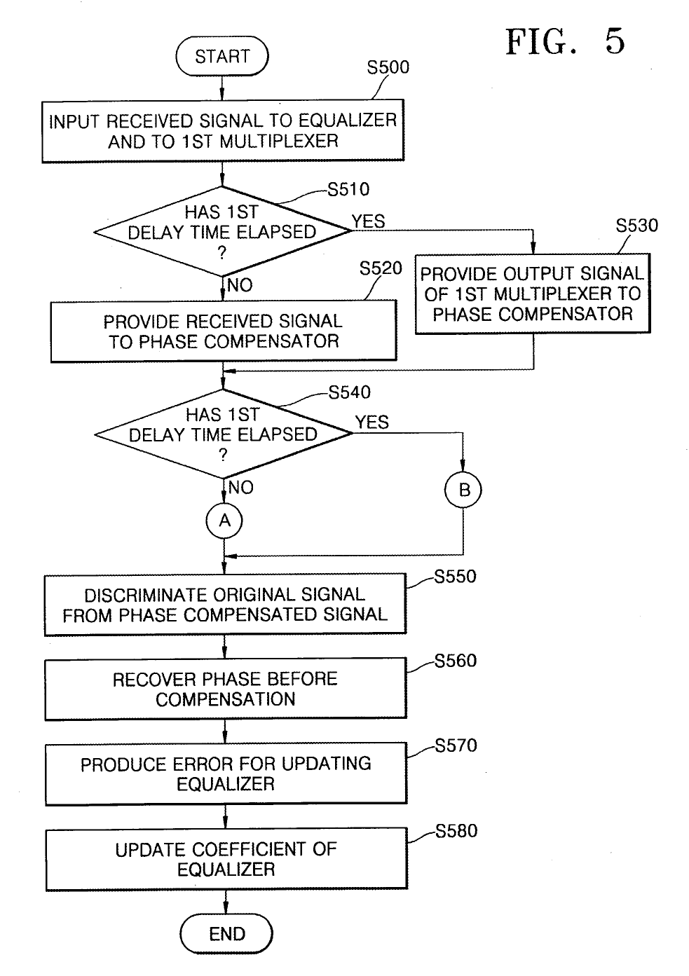

FIG. 5 is a flow chart for explaining a method of compensating for phase errors according to the present invention. Referring to FIG. 5, a received signal is inputted to the equalizer 210 and the first multiplexer 220 (step S500). The first multiplexer 220 checks whether the internal delay time of the equalizer 210 has elapsed (step S510). In the event that the internal delay time of the equalizer 210 has not elapsed, the first multiplexer 220 provides the received signal to the phase compensator 230 (step S520). If it is determined that the internal delay time of the equalizer 210 has elapsed, then the first multiplexer 220 provides the signal inputted from the first multiplier 260 to the phase compensator 230 (step S530). If the center tap of the equalizer 210 is the k-th tap 216-5, then there is no output until k-1 symbols are inputted to the equalizer 210 because the input of the equalizer 210 is multiplied by taps having a value of zero.

The demultiplexer 231 checks starting from the time when data is first inputted to the phase compensator 230 whether the internal delay time of the equalizer 210 has elapsed (step S540). If the internal delay time of the equalizer 210 has not elapsed, then the phase compensator 230 performs step A in which the phase compensator 230 operates as a first stage phase compensator before the internal delay time elapses. When the internal delay time elapses, then the phase compensator 230 performs step B in which the phase compensator 230 operates as a second stage phase compensator.

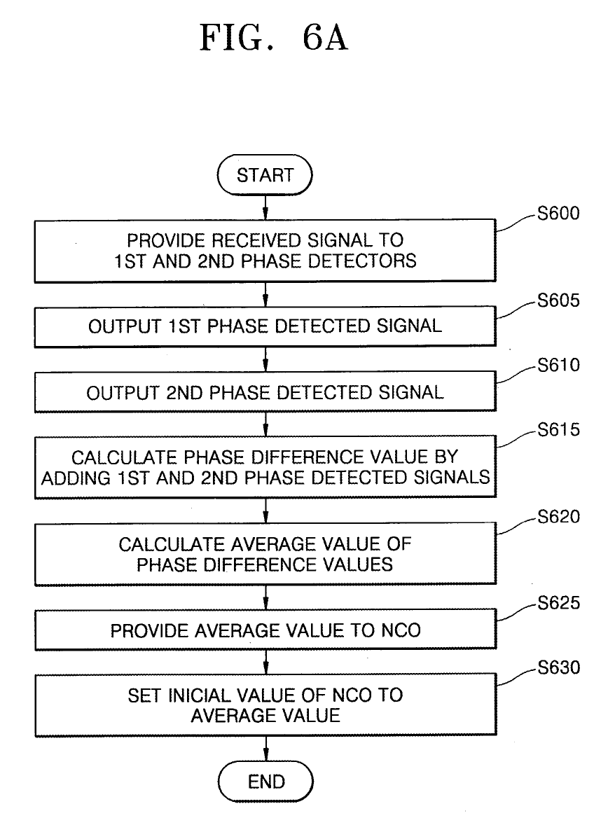

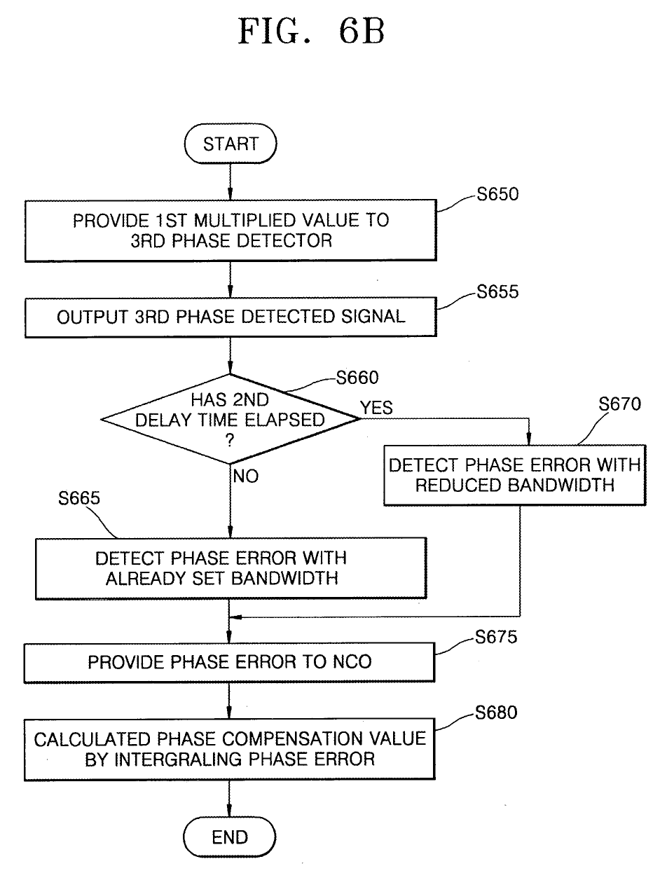

FIG. 6A is a flow chart for explaining processes of step A in which the phase compensator 230 operates as the first stage phase compensator. Referring to FIG. 6a, the demultiplexer 231 provides the signal inputted from the first multiplexer 230 to the first phase detector 232 and the second phase detector 233 (step S600). The first phase detector 232 detects phase errors of the signal inputted from the demultiplexer 231 and outputs a first phase detected signal (step S605). The second phase detector 233 detects phase errors corresponding to integer multiples of π/2 from the phase difference between the signal inputted from the demultiplexer 231 and a series of training signals, and outputs a second phase detected signal (step S610).

The adder 234 adds the first phase detected signal and the second phase detected signal, and calculates phase difference values (step S615). The averaging unit 235 averages the phase difference values and calculates an average value (step 620). The second multiplexer 238 provides the average value to the NCO 239 (step 625), and the NCO 239 resets the average value to an initial value of the second stage operation (step S630).

FIG. 6B is a flow chart for explaining processes of step B in which the phase compensator 230 operates as a second stage phase compensator. Referring to FIG. 6b, if it is determined that the internal delay time of the equalizer 210 has elapsed, then the demultiplexer 231 provides the signal inputted from the first multiplexer 220 to the third phase detector 236 (step S650). The third phase detector 236 detects phase errors of the signal inputted from the demultiplexer 231 and outputs a third phase detected signal (step S655).

The loop filter 237 checks whether a second delay time that is experimentally determined has elapsed (step S660). The loop filter 237 detects and outputs phase errors from the third phase detected signal with already determined bandwidth before the second delay time elapses (step S665). If it is determined that the second delay time has elapsed, the bandwidth of the loop filter 237 is reduced. Then, the loop filter 237 detects and outputs phase errors from the third phase detected signal with a reduced bandwidth (step S670).

The second multiplexer 238 provides the phase errors inputted from the loop filter 237 to the NCO 239 (step 675). The NCO 239 integrates the phase errors with a base of an initial value determined through step A to obtain a phase difference, and determined ε^{jw}, which is used to compensate for the phase and is provided to the first multiplier 260 (step S680).

As described above, since the operation of the phase compensator 230 is different according to whether or not the internal delay time of the equalizer 210 has elapsed, the phase compensator 230 can compensate only for remaining phase errors on the basis of the time when the phase compensator 230 operates as a second stage phase compensator.

The signal discriminator 240 discriminates an original signal from the signal inputted from the first multiplexer 220, and provides the original signal to the phase compensator 230, the subtracting unit 290 and the third multiplier 280 (step S550). Then, the second switch 295-2 operates to provide a value of the discriminated signal of the signal discriminator 240 to the subtracting unit 290 and to the third multiplier 280 starting from the second stage of the phase compensation. The signal provided to the phase compensator 230 is provided to detect phase errors using the first phase detector 232 and the third phase detector 236. Meanwhile, another input signal to the subtracter 290 is provided from the first multiplexer 220. The first switch 295-1 is provided between the first multiplexer 220 and the subtracting unit 290 in order to operate the subtracting unit 290 starting from the second stage of the phase compensation.

The second multiplier 270 multiplies errors obtained through the subtracting unit 290 by the output signal of the phase compensator 230 in order to update the coefficient of the equalizer 210, and recovers the phase before compensation (step S560). The third multiplier 280 multiplies the signal passing through the signal discriminator 240 by the output signal of the phase compensator 230 and provides the discriminated signal to the backward equalizer, and recovers the phase before compensation. The error controller 250 produces an error for updating the equalizer based upon the signal inputted from the second multiplier (step 570). Coefficient of the equalizer is updated with the updating error inputted from the error controller 270 (step S580).

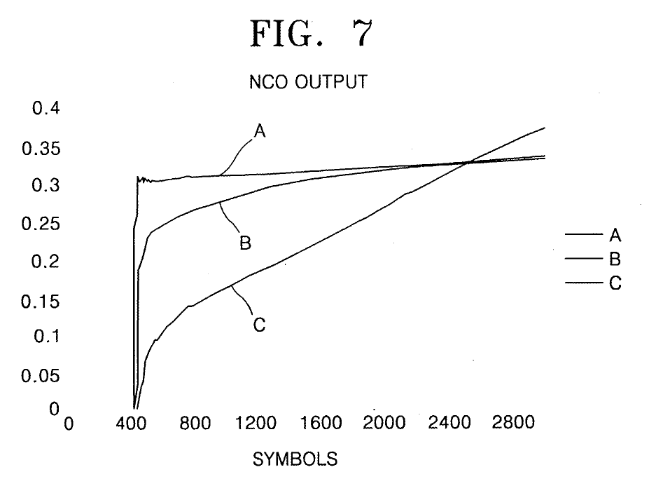

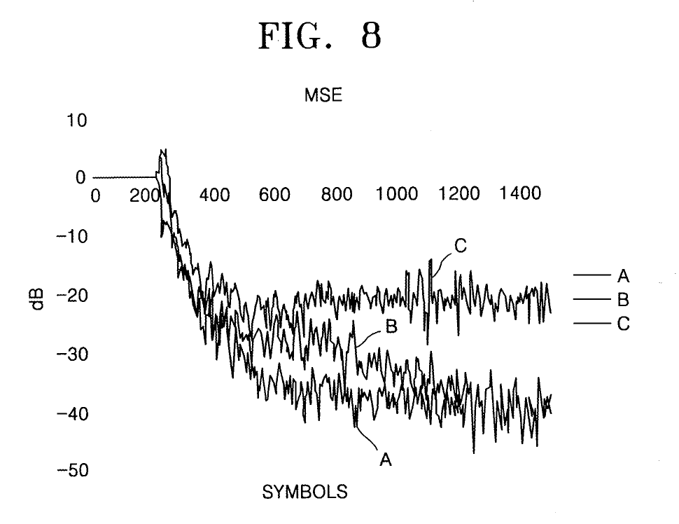

FIGS. 7 and 8 show experimental results of channel equalization using an apparatus for compensating for the phase error of a digital signal according to the present invention. For the purpose of the experiments, test channel number 8 of HomePNA 2.0 (Home Phone-line Network Alliances) was used as a channel, and a frequency offset was added. In FIGS. 7 and 8, graph A is the experimental result when all of the steps (a) through (c) in the operation of the apparatus for compensating for phase errors of a digital signal according to the present invention are used, graph B is the result when steps (b) and (c) are used, and graph (c) is the result when only the step (c) is used.

Referring to FIG. 7, it is understood that in the case of graph A, the NCO value converges and stabilizes most quickly. In Graph B, phase is tracked slower than in graph A, and in graph C, phase tracking is not performed smoothly. Referring to FIG. 8, it is understood how the results of such phase compensation affect the entire channel equalization. Mean square error (MSE) converges most quickly in case A, case B requires more time than case A for convergence, and case C does not converge smoothly. The time difference in convergence between case A and case B shows that there is a significant difference in performance in burst mode modems that use a limited series of training signals.

While the present invention has been particularly shown and described with reference to preferred embodiments thereof, it will be understood by those of ordinary skill in the art that various changes in form and details may be made therein without departing from the spirit and scope of the present invention as defined by the appended claims.

According to the present invention, since the equalizer stops operating during an internal delay time of the equalizer and, then, operates after most of the phase errors have been removed, it is possible to reduce a burden on an equalizer to compensate for phase errors so that the equalizer is dedicated to removing interference between symbols. Further, since the equalizer is dedicated to removing the interference between symbols, performance of channel equalization is improved and phase compensating time is predominantly reduced. Furthermore, since the phase compensating time is reduced, there is provided an improved phase compensator appropriate to burst mode receivers that perform phase compensation as well as amplitude compensation within a short time because of a short series of training signals.

What is claimed is:

1. An apparatus for compensating for phase errors of a digital signal comprising:
an equalizing means for outputting, when a first predetermined delay time elapses, an equalized signal in which an amplitude distortion of a received signal due to a channel is compensated for;
a first multiplying means for multiplying, in complex form, the equalized signal by a compensation signal in which phase is compensated for and for outputting a first multiplied value;
a first multiplexing means for selectively outputting either the received signal or the first multiplied value inputted from said first multiplying means based upon whether the first predetermined delay time has elapsed; and
a phase compensation means for setting an initial value of a local oscillator based upon an average value of phase errors of the received signal inputted from said first multiplexing means before the first predetermined delay time elapses, and for removing phase errors existing in the first multiplied value provided from said first multiplexing means after the first predetermined delay time elapses.

2. The apparatus for compensating for phase errors of a digital signal according claim 1, further comprising:
a signal discriminating means for discriminating an original signal from a signal inputted from said first multiplexing means;
a subtracting means for comparing input and output signals of said signal discriminating means and for detecting errors;
a second multiplying means for multiplying an output signal of said subtracting means by an output signal of said phase compensation means and for outputting a second multiplied value;
a third multiplying means for multiplying the output signal of said signal discriminating means by the output signal of said phase compensation means and for outputting a third multiplied value;
a first switching means for providing the output signal of said first multiplexing means to said subtracting means when the first predetermined delay time elapses;
a second switching means for providing the output signal of said signal discriminating means to said subtracting means and to said third multiplying means when the first predetermined delay time elapses; and
an error controlling means for controlling an error value corresponding to the second multiplied value and for providing the error value to said equalizing means.

3. The apparatus for compensating for phase errors of a digital signal according to claim 2, wherein said equalizing means comprises:
a forward equalizing means for equalizing the received signal;
a backward equalizing means for outputting the signal inputted from said signal discriminating means;
an adding means for adding an output signal of said forward equalizing means and an output signal of said backward equalizing means, and for outputting an added value; and
a coefficient updating means for updating an operational coefficient of the forward equalizing means and the backward equalizing means based upon the error value inputted from said error controlling means after a second predetermined delay time elapses.

4. The apparatus for compensating for phase errors of a digital signal according to claim 2, wherein said phase compensation means comprises:
a first phase detecting means for detecting phase errors of a signal inputted from a first multiplexing means and for outputting first phase detected signals;
a second phase detecting means for detecting phase errors corresponding to integer multiples of π/2 from phase differences between the signal inputted from the first multiplexing means and a series of training signals, and for outputting second phase detected signals;
a third phase detecting means for detecting phase errors of the signal inputted from the first multiplexing means and for outputting third phase detected signals;
an adding means for adding the first phase detected signals and the second phase detected signals, and for outputting phase difference values;
an averaging means for averaging the phase difference values, and for outputting an average value;
a loop filtering means for outputting phase errors discriminated from the third phase detected signals;
a demultiplexing means for providing the signal inputted from the first multiplexing means to said first phase detecting means and to said second detecting means before a first predetermined delay time elapses, and to said third phase detecting means after the first predetermined delay time elapses;
a second multiplexing means for outputting the average value before the first predetermined delay time elapses and for outputting the phase errors after the first predetermined delay time elapses; and
a numerically controlled oscillating means for integrating the phase errors inputted from said second multiplexing means when the first predetermined delay time elapses and for outputting a compensation value, wherein the average value inputted from said second multiplexing means is set as an initial value of the numerically controlled oscillating means.

5. The apparatus for compensating for phase errors of a digital signal according to claim 4, wherein the bandwidth of the loop filtering means is reduced after the second predetermined delay time elapses.

6. The apparatus for compensating for phase errors of a digital signal according to claim 2, wherein said error controlling means provides said equalizing means with a zero (0) value before the second predetermined delay time elapses and with the error value corresponding to the second multiplied value inputted from said second multiplying means after the second predetermined delay time elapses.

7. The apparatus for compensating for phase errors of a digital signal according to claim 1, wherein said phase compensation means comprises:
a first phase detecting means for detecting phase errors of the signal inputted from said first multiplexing means and for outputting first phase detected signals;
a second phase detecting means for detecting phase errors corresponding to integer multiples of π/2 from phase differences between the signal inputted from said first multiplexing means and a series of training signals, and for outputting second phase detected signals;
a third phase detecting means for detecting phase errors of the signal inputted from said first multiplexing means and for outputting third phase detected signals;
an adding means for adding the first phase detected signals and the second phase detected signals, and for outputting phase difference values;
an averaging means for averaging the phase difference values, and for outputting an average value;
a loop filtering means for outputting phase errors discriminated from the third phase detected signals;
a demultiplexing means for providing the signal inputted from said first multiplexing means to said first phase detecting means and to said second detecting means before the first predetermined delay time elapses, and to said third phase detecting means after the first predetermined delay time elapses;
a second multiplexing means for outputting the average value before the first predetermined delay time elapses and for outputting the phase errors after the first predetermined delay time elapses; and
a numerically controlled oscillating means for integrating the phase errors inputted from said second multiplexing means when the first predetermined delay time elapses and for outputting a compensation value, wherein the average value inputted from said second multiplexing means is set as an initial value of the numerically controlled oscillating means.

8. The apparatus for compensating for phase errors of a digital signal according to claim 7, wherein said the bandwidth of the loop filtering means is reduced after the second predetermined delay time elapses.

9. A method for compensating for phase errors of a digital signal comprising the steps of:
calculating an average phase error value of a received signal before a first predetermined delay time elapses;
outputting, after a first predetermined delay time elapses, an equalized signal in which phase distortion of the received signal due to a channel is compensated for;
outputting a compensation signal corresponding to phase errors of the equalized signal;
multiplying, in complex form, the equalized signal by the compensation signal and outputting a first multiplied value; and
removing phase errors existing in the first multiplied value.

10. The method for compensating for phase errors of a digital signal according to claim 9 further comprising the steps of:
discriminating an original signal from the received signal and the equalized signal, which are selectively inputted based upon whether the first predetermined delay time has elapsed, and outputting a discriminated signal;
calculating a difference value between the discriminated signal and the compensation signal when the first predetermined delay time elapses, and multiplying the difference value by the compensation signal and outputting a second multiplied value;
producing an error value corresponding to the second multiplied value;
updating an operational coefficient of the equalizer based on the error value; and
multiplying the discriminated signal by the compensation signal when the first predetermined delay time elapses and providing a third multiplied value to the equalizer.

11. The method for compensating for phase errors of a digital signal according to claim 10, wherein the step of updating an operational coefficient is performed after a second predetermined delay time elapses.

12. The method for compensating for phase errors of a digital signal according to claim 10, wherein in the step of producing the error value, a zero (0) value is outputted as the error value before the second predetermined delay time elapses, and the second multiplied value is outputted as the error value after the second predetermined delay time elapses.

13. The method for compensating for phase errors of a digital signal according to claim 10, wherein the step of outputting the compensation signal includes the steps of:
(a) detecting phase errors of the received signal and outputting first phase detected signals;
(b) detecting phase errors corresponding to integer multiples of π/2 from error differences between the received signal and a series of training signals and outputting second phase detected signals;
(c) adding the first phase detected signals and the second phase detected signals, and outputting phase difference values;
(d) averaging the phase difference values and outputting an average value;
(e) detecting phase errors with respect to the first multiplied value and outputting third phase detected signals;
(f) receiving the third phase detected signals and discriminating the phase errors; and
(g) integrating the phase errors with the average value as an initial value of a numerically controlled oscillator when the first predetermined delay time elapses and outputting a compensation value, wherein the steps (a) through (d) are repeated before the first predetermined delay time elapses, and the steps (e) through (g) are performed after the first predetermined delay time elapses.

14. The method for compensating for phase errors of a digital signal according to claim 13, wherein the step of discriminating phase errors includes the step of discriminating the phase errors by reducing a bandwidth for discriminating the phase errors when the second predetermined time elapses.

15. The method for compensating for phase errors of a digital signal according to claim 9, wherein the step of outputting the compensation signal includes the steps of:
(a) detecting phase errors of the received signal and outputting first phase detected signals;
(b) detecting phase errors corresponding to integer multiples of π/2 from error differences between the received signal and a series of training signals and outputting second phase detected signals;
(c) adding the first phase detected signals and the second phase detected signals, and outputting phase difference values;
(d) averaging the phase difference values and outputting an average value;
(e) detecting phase errors with respect to the first multiplied value and outputting third phase detected signals;
(f) receiving the third phase detected signals and discriminating the-phase errors; and
(g) integrating the phase errors with the average value as an initial value of a numerically controlled oscillator when the first predetermined delay time elapses and outputting a compensation value, wherein the steps (a) through (d) are repeated before the first predetermined delay time elapses, and the steps (e) through (g) are performed after the first predetermined delay time elapses.

16. The method for compensating for phase errors of a digital signal according to claim 15, wherein the step of discriminating phase errors includes the step of discriminating the phase errors by reducing a bandwidth for discriminating the phase errors when the second predetermined time elapses.
